(19) United States
(12) Patent Application Publication
(10) Pub. No.: US 2024/0234546 A1
(43) Pub. Date: Jul. 11, 2024

(54) METHOD FOR PRODUCING A VERTICAL SEMICONDUCTOR DEVICE WITH EPITAXIALLY GROWN III-V EPITAXY USING THE SUBSTRATE SEVERAL TIMES, AND CORRESPONDING SEMICONDUCTOR DEVICE, IN PARTICULAR BASED ON GALLIUM NITRIDE

(71) Applicant: Robert Bosch GmbH, Stuttgart (DE)

(72) Inventors: Christian Huber, Ludwigsburg (DE); Stefan Regensburger, Renningen (DE)

(21) Appl. No.: 18/405,418

(22) Filed: Jan. 5, 2024

(30) Foreign Application Priority Data
Jan. 10, 2023 (DE) 10 2023 200 123.3

(51) Int. Cl. H01L 29/66; H01L 21/268; H01L 29/20; H01L 29/78

(52) U.S. Cl. CPC H01L 29/66712; H01L 21/268; H01L 29/2003; H01L 29/7802

(57) ABSTRACT

A method for producing a vertical semiconductor device, in particular a transistor. The device has a semiconductor layer structure for forming a semiconductor device based on gallium nitride and at least two, preferably three, electrodes arranged vertically one above the other, wherein the semiconductor layer structure is applied, in particular grown, on a substrate. The method includes forming a semiconductor layer structure comprising at least one layer based on gallium nitride on the substrate, in particular a foreign substrate. The method includes the introduction of laser radiation into the semiconductor layer structure or the substrate, wherein the wavelength of the laser radiation is greater than the optical band gap of gallium nitride, so that the laser radiation causes at least the substrate to separate from at least part of the semiconductor layer structure.

### FIELD

The present invention relates to a method for producing a vertical semiconductor device, in particular transistors, having a semiconductor layer structure for forming the semiconductor device with an epitaxially grown III-V epitaxy, in particular based on gallium nitride (GaN). The present invention also relates to a semiconductor device produced in this way.

### BACKGROUND INFORMATION

In principle, vertical semiconductor devices are conventional. With these, the final connection electrodes are arranged on two vertically opposite sides of the semiconductor device, in particular the corresponding semiconductor layer structure for forming a semiconductor device, so that space-saving contacting and a vertical current flow and/or field progression are achieved, which are correspondingly advantageous both for the performance characteristics and for the space consumption.

The formation of such vertical semiconductor devices utilizing a grown III-V epitaxy, in particular based on gallium nitride, is particularly desirable, since these allow lower on-resistances (electrical resistance in the conduction state) with simultaneously higher breakdown field strengths/breakdown voltages than comparable components based on silicon or silicon carbide.

Since gallium nitride is a relatively expensive material and the substrate used is removed or at least partially removed in any event within the framework of the processing of the semiconductor element, in particular for the formation of a rear-side or vertically lower electrode, in particular a drain electrode, approaches using a foreign substrate and the corresponding formation of a heteroepitaxy based on foreign substrates have substantially been pursued in the past. The disadvantage of previous approaches is that, when the semiconductor layer structure, for example a contact semiconductor layer, is exposed at the rear or vertically at the bottom, the substrate is removed destructively or partially removed, and so a large proportion of the substrate is destroyed both when using a native substrate, such as gallium nitride, to form a homoepitaxy and when using foreign substrates to form a heteroepitaxy. Accordingly, the particular consumption of the substrate is a less sustainable part of the processing and therefore also a cost item that should not be neglected in the production of corresponding semiconductor devices.

### SUMMARY

A method according to the present invention for producing vertical semiconductor devices having a semiconductor layer structure for forming a semiconductor device based on gallium nitride may have an advantage that a separation of the substrate from the semiconductor layer structure or part of the semiconductor layer structure is carried out and integrated into the production method in such a way that, on the one hand, sufficient mechanical stability is ensured at all times during the method and, on the other hand, the substrate and, if applicable, further layers that are directly or indirectly deposited, in particular grown, on the substrate can subsequently be reused, in order to apply or grow a semiconductor layer structure thereon to form a semiconductor device.

Against the background of the above explanations, it is therefore provided, in the method according to an example embodiment of the present invention for producing a vertical semiconductor device, in particular a transistor, having a semiconductor layer structure for forming a semiconductor device based on gallium nitride and at least two, preferably three, electrodes arranged vertically one above the other, wherein the semiconductor layer structure is applied, in particular grown, on a substrate, that subsequent to the formation of the semiconductor layer structure comprising at least one layer based on gallium nitride on the substrate, in particular a foreign substrate, laser radiation is introduced into the semiconductor layer structure or the substrate, wherein the wavelength of the laser radiation is greater than the optical band gap of gallium nitride, so that the laser radiation causes at least the substrate to separate from at least part of the semiconductor layer structure.

In other words, this means that at a correspondingly suitable point in time in the entire production method of the semiconductor device, a removal, in particular a separation, of at least the substrate is carried out, which separates the substrate from the semiconductor layer structure or part of the semiconductor layer structure in a non-destructive but conservative manner, so that the substrate can subsequently be reused for the same or preceding part of the production method of the semiconductor devices.

Thus, the method according to the invention enables a significantly more sustainable and resource-saving production, as will be shown in detail below, even using native substrate made of gallium nitride, wherein the substrate can be used at least several times for the process or the production method before a new substrate has to be used due to wear caused by the separation or the subsequent processing or reprocessing, which can then also be used at least several times.

Advantageous further developments of the method according to the present invention are disclosed herein.

According to a first, particularly advantageous embodiment of the method of the present invention, it can be provided that, prior to the introduction of the laser radiation, a carrier material is arranged on a side of the semiconductor layer structure facing away from the substrate and/or is bonded to the semiconductor layer structure. In technical jargon, the term “front-side” attachment of a carrier material is regularly used, wherein this is intended to express the fact that the carrier material is to be arranged and/or fastened on a plane that is at the top in the vertical direction and thus opposite the substrate. The carrier material can advantageously ensure that the semiconductor layer structure has sufficient mechanical stability during and after the separation of the substrate by the introduction of the laser radiation.

As will be discussed in detail below, the laser radiation can be emitted in a vertical direction, either through the semiconductor layer structure or in a vertical direction through the rear side of the substrate. Alternatively, the laser radiation can also be introduced or irradiated laterally at right angles to the vertical direction and thus in a lateral plane of the semiconductor layer structure.

If an introduction or irradiation in the vertical direction is to be effected through the semiconductor layer structure and, according to the advantageous embodiment of the present invention described above, therefore also through the carrier material, it is particularly advantageous if the carrier material has an optical band gap that is larger than the optical band gap of the material of the semiconductor layer structure in which the separation is formed or carried out. If a separating layer is provided, described in detail below, in which the separation is effected or formed by the laser radiation, it can be particularly advantageous for the optical band gap of the carrier material to be larger than the optical band gap of the separating layer.

According to a further, particularly preferred embodiment of the method of the present invention, it can be provided that a vertically upper metallization of the semiconductor layer structure is formed prior to the introduction of the laser radiation and the laser radiation is introduced only into gaps in the lateral surface of the semiconductor layer structure that do not contain any metallization. A lateral surface is a surface that is perpendicular to the vertical direction.

Metallization within the meaning of the present invention is to be regarded in particular as metal structures for forming a gate electrode, a source electrode, a field plate and/or a P-electrode. Depending on the method control and the semiconductor device to be produced, it may be advantageous to carry out this metallization before the laser radiation is introduced, in particular irradiated, and/or before a carrier material is applied on the front side or vertically on top, even if this limits the area available for irradiation or introduction of the laser radiation. This is because irradiation or introduction into or onto the metallization would lead to unwanted and undesirable heating of the metallization and the surrounding structures and could damage the semiconductor layer structure. However, it is advantageously possible to form optical structures, for example waveguide structures, vertically below the metallization, which scatter or guide the laser radiation into regions that would otherwise remain covered or shadowed by the metallization in the vertical direction, even if the introduction or irradiation of the laser radiation is limited in the lateral area and past a metallization and/or through a carrier material, in order to achieve effective full-surface separation from at least the substrate.

The formation of the metallization prior to the introduction of the laser radiation can also be particularly advantageous if the laser radiation is irradiated at right angles to the vertical direction, i.e., in the lateral surface, and/or is irradiated from the rear side or from vertically below through the substrate.

Alternatively, in particular if an irradiation of the laser radiation in the vertical direction from vertically upwards is particularly advantageous or particularly desired and, in addition, an irradiation of the laser radiation over as large a surface as possible is advantageous, it can be provided in a further, particularly preferred embodiment of the method of the present invention that the bonding of the semiconductor layer structure to a front-side or vertically upper carrier substrate and the subsequent introduction or irradiation of the laser radiation is effected before a vertically upper metallization of the semiconductor layer structure is formed. With such a method control, it can then be advantageously provided that, after the conservative separation of the substrate and possibly further layers of the semiconductor layer structure, rear-side or vertically lower processing, for example the formation of a drain electrode and the connection and/or contacting with a conductive carrier material, is performed or is carried out up to a point or method stage at which sufficient mechanical stability is given before the front-side or vertically upper carrier material is removed. After a corresponding method step, in which the carrier material is removed, the corresponding vertically upper metallization can be formed on the front side or in the vertically upper regions or can be made up for after the separation from at least the substrate has also been effected or has been carried out.

In a further, particularly preferred embodiment of the present invention, it can be provided that the separation takes place along a surface of the substrate. This is possible, for example, if silicon or monocrystalline silicon, in particular with a 111 lattice orientation, is used as the substrate. When using laser radiation with a wavelength greater than the gallium-nitride band gap, a large proportion of the laser radiation is absorbed on the silicon-111 surface and can therefore be used to form the separation. In this case, the separated silicon substrate can be used subsequently, preferably after chemical and/or mechanical polishing, to perform a corresponding epitaxy or form a semiconductor layer structure. The separated semiconductor layer structure can be further processed in the usual way to form the semiconductor devices. The laser radiation can subsequently be irradiated from vertically upwards to vertically downwards, either over the full surface without metallization or through gaps between the metallization, as described above.

This cycle can be repeated until the thickness of the substrate, which decreases in each cycle due to the separation process and the subsequent preparation or processing, in particular due to polishing, is no longer sufficient for the epitaxy of a semiconductor layer structure based on gallium nitride.

According to a further, also particularly preferred embodiment of the method of the present invention, it can be provided that the separation takes place in an intermediate layer that is formed vertically above the substrate, in particular grown thereon, but is formed vertically below a drift layer and/or vertically below a contact semiconductor layer.

Both when using a native substrate made of gallium nitride and when using foreign substrates, such as poly-aluminum nitride (poly-AlN), silicon, sapphire, and the like, it may be necessary to initially form auxiliary layers, such as so-called buffers and/or engineered layers, on the substrate surface of the substrate or foreign substrate due to the necessary lattice matching and due to the consideration of different thermal expansions before, for example, a contact semiconductor layer or a drift layer is deposited or grown. With such methods, it may be particularly advantageous if, in addition to the auxiliary layers provided, an intermediate layer is formed on the substrate in which the separation is effected or takes place. This leads to the advantageous effect that upon the separation of the substrate, the corresponding preparatory and necessary auxiliary layers on the substrate, which however have no significant influence on the functioning of the semiconductor device, can also be preserved together with the substrate for subsequent epitaxy using the same substrate and can be completely or at least largely reused. Furthermore, this leads to the advantageous effect that subsequent post-processing of the vertically lower regions or separation regions of the separated semiconductor layer structure, for example for removing or structuring the auxiliary layers, can be minimized or completely omitted.

It is particularly advantageous if a drift layer of the semiconductor layer structure and/or a vertically lower contact semiconductor layer of the semiconductor layer structure are arranged within the framework of separation in such a way that they are located vertically above the intermediate layer and remain bonded to the semiconductor layer structure after separation.

According to a further, particularly advantageous embodiment of the method of the present invention, it can be provided that the semiconductor layer structure is produced on a substrate and/or layers applied thereon, which have previously already been separated by laser radiation from a semiconductor layer structure applied thereon and/or that, after the separation of at least the substrate from at least part of the semiconductor layer structure, the substrate and/or the layers remaining thereon after the separation are prepared for reuse of the substrate to form a semiconductor layer structure based on gallium nitride. As already explained above, this enables the substrate to be reused, particularly preferably together with auxiliary layers already formed on the substrate, such as a buffer layer, engineered layers or the like, to the extent that these are required.

In a further, particularly preferred embodiment of the method of the present invention, it can be provided that after the separation of at least the substrate, a vertically lower electrode, preferably a gate electrode, is formed, in particular deposited or grown, on the separated semiconductor layer structure. In principle, this can be effected in the usual way. As will be explained in detail below, depending on the method control and design of the separation, appropriate preparation and processing, in particular material removal, may be necessary. However, it is particularly preferable that the method control also takes place in such a way that the electrode, preferably the drain electrode, can be formed directly after the separation of at least the substrate.

In a further, particularly advantageous embodiment of the method of the present invention, it can be provided that the formation of the semiconductor layer structure on the substrate also comprises the formation of a separating layer, preferably of an indium-gallium-nitride material (InₓGaₓ₋₁N), which is separated by the introduction of the laser radiation, wherein preferably the separation is formed within the separating layer.

Advantageously, it can be provided that the separating layer and the intermediate layer already advantageously disclosed above form or represent one and the same layer.

If the wavelength of the laser radiation is selected accordingly, it can be ensured that the absorption of the laser radiation substantially takes place in the separating layer, preferably in the indium-gallium-nitride layer, and divides or splits it, as a result of which separation at least from the substrate can be achieved, without the substrate and any remaining layers arranged thereon, which are arranged and formed vertically below the separating layer, being destroyed or otherwise rendered unusable for reuse.

According to a further, particularly preferred variant of the method of the present invention, it can be provided that the separation by means of the introduction or irradiation of laser radiation is supported by the coupling of ultrasound and/or megasound into the substrate and/or the semiconductor layer structure. It has been shown that the corresponding acoustic coupling supports the effect of the laser radiation or the effects caused by the absorption of the laser radiation in an intermediate layer, separating layer or on a surface of the substrate in such a way that improved lateral crack formation and the associated separation are achieved.

The present invention also comprises a semiconductor device produced according to one of the embodiments of the present invention described above. By reusing the substrate, this can be produced with a particularly low use of resources and thus at a correspondingly low cost.

Further advantages, features, and details of the present invention can be found in the following description of preferred embodiments of the present invention and with reference to the figures.

### BRIEF DESCRIPTION OF THE DRAWINGS

FIG. 1A to FIG. 1E show schematic sections through a layer structure in different processing stages of the method according to an example embodiment of the present invention for forming a semiconductor device according to an example embodiment of the present invention with further use or reuse of the substrate.

FIG. 2A to FIG. 2D show schematic sections through layer structures at various processing stages of the method according to an example embodiment of the present invention in an alternative method control of the method according to an example embodiment the present invention.

FIG. 3 shows a schematic section through a semiconductor layer structure according to an example embodiment the present invention using an alternative method control according to an example embodiment of the present invention.

FIG. 4 shows a schematic section through a semiconductor layer structure according to an example embodiment of the present invention using an alternative method control according to an example embodiment of the present invention.

FIG. 5 shows a schematic section through a semiconductor layer structure according to the present invention based on an alternative method control according to an example embodiment of the present invention.

FIG. 6A to FIG. 6F show schematic sections through layer structures in different processing stages of the method according to the present invention for forming a semiconductor device according to an example embodiment of the present invention by reusing the substrate when using an alternative substrate material.

### DETAILED DESCRIPTION OF EXAMPLE EMBODIMENTS

Identical components or elements with the same function are marked with the same reference signs in the figures.

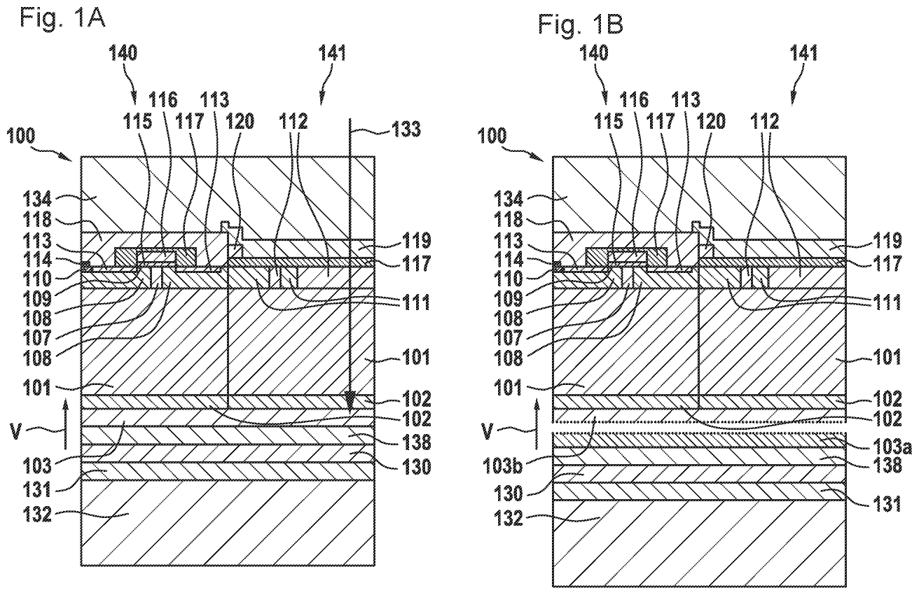

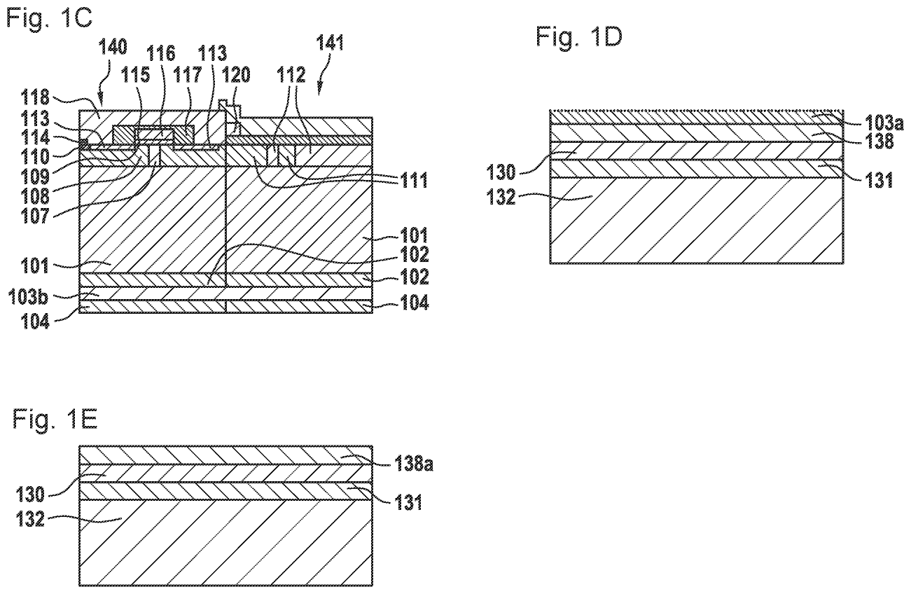

FIG. 1A shows a transistor unit cell 140 and an edge termination cell 141 laterally side by side, wherein the transistor unit cell 140 is repeated several times laterally perpendicular to the vertical direction V and is terminated in the lateral edge region by an edge termination cell 141. The illustration shows a vertical transistor 100 with completed front-side processing on a substrate 132, for example a foreign substrate. For the final formation of the transistor 100, the semiconductor layer structure still requires a rear electrode, preferably a drain electrode.

So-called “engineered layers” 131 are deposited on the substrate 132 for lattice matching and to compensate for different thermal expansion coefficients, which are followed vertically by a buffer layer 130, preferably made of aluminum-gallium nitride. A further gallium nitride layer 138 can be formed thereon, which is followed in the vertical direction by a separating layer 103. A slightly n-doped contact semiconductor layer 102 based on gallium nitride is formed on the separating layer 103. An n-doped drift layer 101 is located thereon.

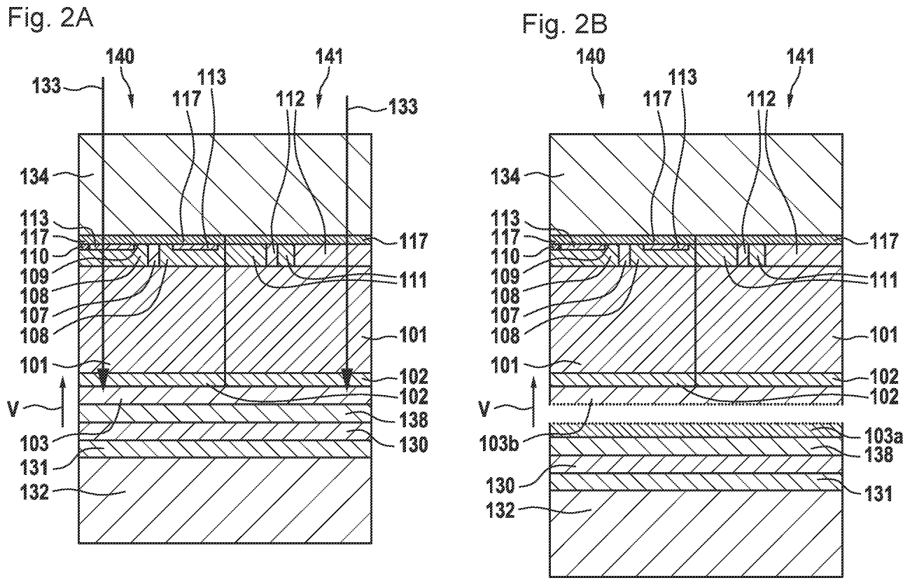

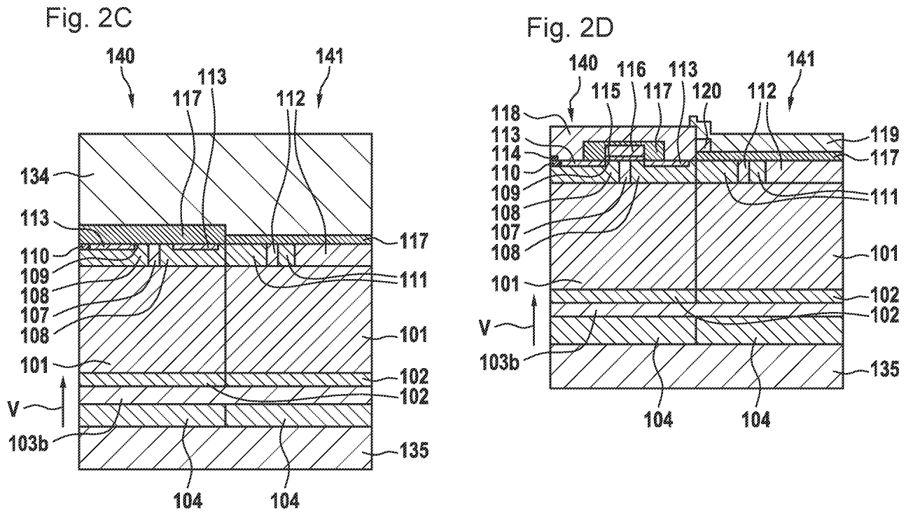

In the exemplary embodiment of FIG. 2A, the following structures are formed on the drift layer 101 to form a VDMOS transistor:

JFET region 107, p-doped body 107, channel interface 109, p-doped regions 110, p-doped shield 111, n-doped shield 112, contact layer 113, p-electrode 114, gate dielectric 115, gate electrode 116, insulating layer 117, source electrode 118, imide 119, field plate 120 along with a carrier material 134.

As shown in FIG. 1A, irradiation of laser radiation 133 is effected between the front-side metallization comprising, for example, source electrode 118, gate electrode 112 and p-electrode 114, which is irradiated from vertically upwards to vertically downwards and passes through both the carrier material 134 and the semiconductor layer structure arranged under the metallization. In the separating layer 103, which preferably consists of indium-gallium-nitride, the laser radiation 133 is absorbed, which, if necessary under the influence or coupling of ultrasound and/or mega-sound, leads to the separating layer 103 separating or splitting. In order to cause the laser radiation 133 to be absorbed only in the interface 103, the optical band gap of the carrier material 134 is advantageously larger than the wavelength of the laser or the laser radiation. Similarly, the wavelength of the laser radiation is preferably greater than the optical band gap of gallium nitride.

The result of the irradiation or introduction of the laser radiation 133 is shown in the illustration in FIG. 1B. The separating layer 103 was divided into a first part 103a and a second part 103b by the irradiation of the laser radiation 133, possibly assisted by the effect of the ultrasound and/or megasound, wherein the first part 103a remains indirectly bonded to the substrate 132 and the second part 103b remains bonded to the semiconductor layer structure, in particular adjacent to the contact semiconductor layer 102.

In the representation of FIG. 1C, the processed transistor 100 is shown after removal of the carrier material 134. The separating layer, in particular the second part 103b, remains in the semiconductor layer structure and is used to improve the contact resistance of the electrode 104, in particular the drain electrode. Particularly advantageously, the second part 103b of the separating layer 103 is formed with a thickness in the vertical direction V of 1 nm to 20 nm. Not shown in FIG. 1C is a method control according to which a carrier, for example an electrically conductive carrier, is subsequently advantageously arranged, in particular bonded, prior to the removal of the carrier material 134 and furthermore preferably after the formation of the electrode 104 vertically at the bottom, i.e., in particular adjacent to the electrode 104, in order to stabilize the transistor 100.

The representation of FIGS. 1D and 1E shows the further use of the lower part 103b, including the substrate 132, separated together with the first part 103a by the separation. The surface of the first part 103a of the separating layer 103 damaged by the laser action is smoothed by chemical and/or mechanical polishing and prepared for subsequent epitaxy. The first part 103a of the separating layer 103 is in this case removed and the polishing stops in the gallium nitride layer 138, which thereby becomes thinner and becomes the reduced gallium nitride layer 138a. Processing can be restarted on the reduced gallium nitride layer 138a, preferably after subsequent application of a separating layer 103, for example of indium gallium nitride, which leads to a state according to the representation of FIG. 1A. The corresponding method is also possible with a native substrate 132 made of gallium nitride. Preferably, the buffer layer 130 and the engineered layers 131 can be omitted. Furthermore, particularly preferably when using a substrate 132 made of gallium nitride, the laser irradiation 133 can be effected in a vertical direction from vertically downwards to vertically upwards through the substrate 132. As a result, there is no restriction of the introduction or irradiation of the laser radiation 133 by the metallizations, in particular the gate electrode 116, the source electrode 118, the field plate 120 and/or the p-electrode 114 on the front side or top side.

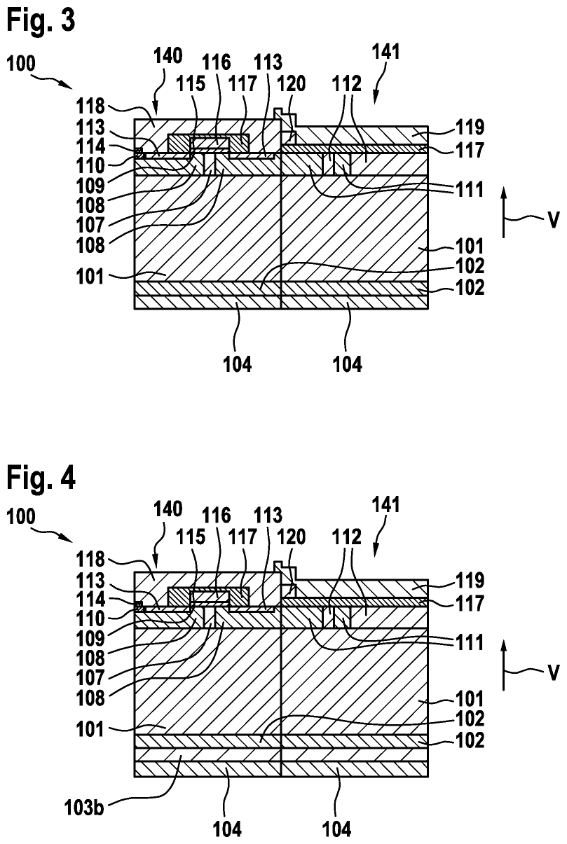

The representation of FIGS. 2A to 2D shows a similar method sequence or a similar process control of the method according to the invention. However, in contrast to the method according to FIGS. 1A to 1E, upon the production and formation of the semiconductor layer structure in the embodiment according to FIGS. 2A to 2D, the formation of metallization is omitted prior to the application of the carrier material 134. Accordingly, in FIGS. 3A to 3C, the source electrode 118, the field plate 120, the gate electrode 116 and the p-electrode 114 have not yet been formed vertically below the carrier material 134. Instead, the carrier material 134 is applied on the insulation 117. As indicated in the representation of FIG. 3A, this enables a full-surface introduction of the laser radiation 133 over the entire lateral surface. After a corresponding separation of the substrate 132 together with the layers 130, 131, 138 formed thereon and the first part 103a of the separating layer 103, as indicated in FIG. 2B, an electrode 104, preferably a drain electrode, can initially be formed, for example, as shown in FIG. 2C, and the connection is made initially with a carrier 135, before the front-side or vertically upper carrier material 134 is removed and the metallization is formed and the carrier 135 is replaced by a conductive carrier 136, as is illustrated in the sectional views of FIGS. 2C and 2D.

FIG. 3 shows an embodiment of a transistor 100 produced according to the method according to the invention. In this case, the electrode 104, in particular the drain electrode, borders directly on the contact semiconductor layer 102. This can be achieved if either no separating layer 103 is used and split or, alternatively, if after separating the separating layer 103 into a first part 103a and a second part 103b prior to the application of the electrode 104, for example by dry etching with chlorine gas (Cl₂), the remaining residues of the second part 103b of the separating layer 103 are removed. As a result, the transition between the contact semiconductor layer 102 and the electrode 104 can have additional roughness due to dry etching damage.

The representation in FIG. 4 shows a section through a layered structure of a transistor 100, which was substantially produced according to the method control of FIGS. 1A-1E. The difference with the embodiment of FIGS. 1A-1E is substantially that the separating layer 103 has additionally received an n-doping during the epitaxial growth. The additional n-doping further reduces the contact resistance to the electrode 104. In this connection, it is particularly advantageous if the second part 103b of the separating layer 103 has a thickness or strength in the vertical direction V of between 1 nm and 20 nm and remains as an intermediate layer between the contact semiconductor layer 102 and the electrode 104.

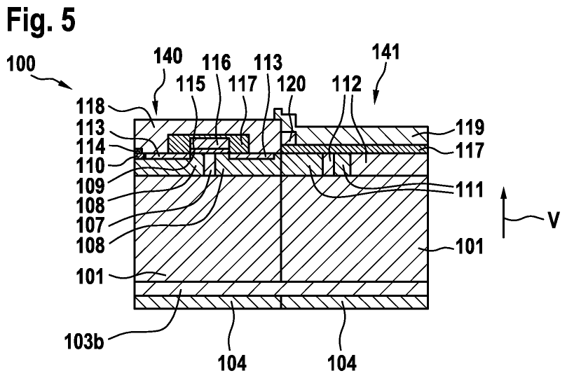

The illustration of FIG. 5 also shows a sectional view of a transistor 100 according to the invention, which was produced using a variant of the method according to the invention. In contrast to the preceding embodiments, the contact semiconductor layer 102 is dispensed with here and instead the drift layer 101 is grown directly on the separating layer 103 within the framework of the epitaxial growth, wherein the separating layer has an n-doping, similar to the embodiment of FIG. 4. In this embodiment, the contact semiconductor layer 102, which is typically 100 nm to 1000 nm thick (extent in the vertical direction V), can be omitted, which in turn means that the drift layer 101 can be made correspondingly thicker or with a correspondingly larger extension in the vertical direction V.

This in turn enables a higher breakdown voltage and/or higher field strengths of the transistor 100.

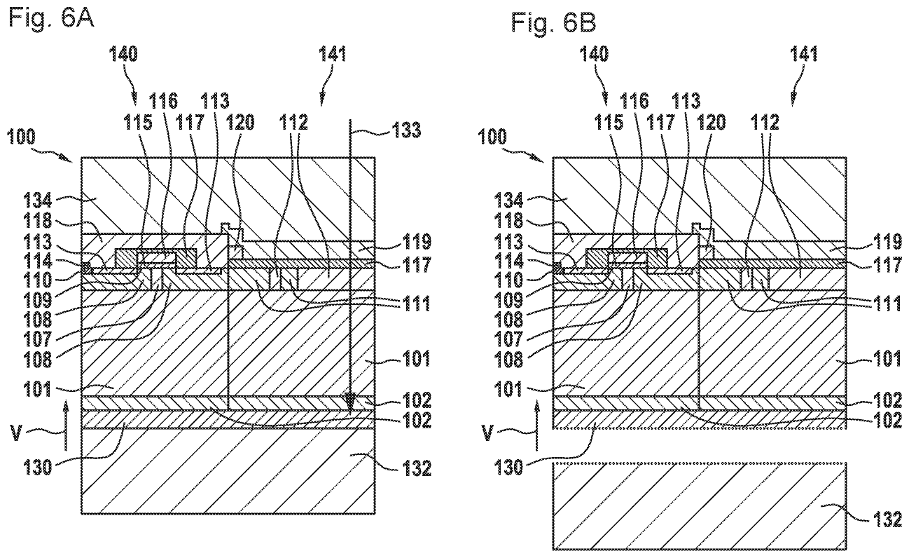

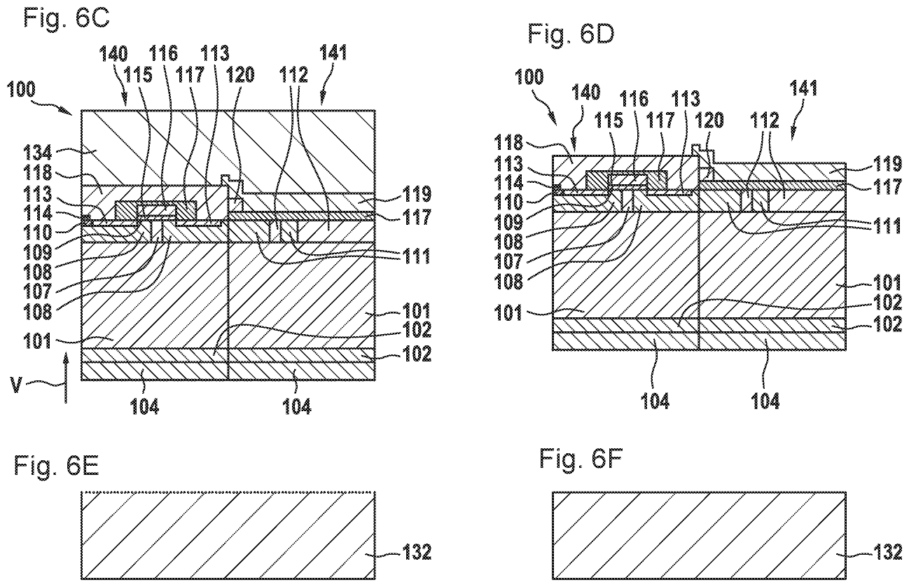

The embodiment of FIG. 6A to 6F shows an alternative method control of the method according to the invention, in which no separating layer 103 is used. Instead, the laser radiation 133 is absorbed directly on a substrate surface of the substrate 132, thereby causing the separation of the substrate 132. The method control according to the representation of FIGS. 7A to 7F is substantially suitable for silicon substrates with a 111 lattice arrangement, or substrates that have a silicon layer with a 111 lattice arrangement as their surface. The substrate 132 made of silicon can be used several times. In the illustrations of FIGS. 6A and 6C, analogous to the procedure according to FIGS. 1A and 1B, laser radiation 133 is introduced through the gaps in the metallization from the front side or from vertically upwards to vertically downwards, wherein the wavelength of the laser radiation 133 is greater than the optical band gap of gallium nitride. The laser radiation is absorbed on the surface of the substrate 132.

The substrate 132 detaches and is prepared again for a new epitaxy by chemical and/or mechanical polishing as shown in the illustration of FIGS. 6E and 6F. The transistor 100 is finished processing, as in the illustration in FIGS. 6C and 6D, substantially by forming the electrode 104 and removing the carrier material 134. In the example of the embodiment of FIG. 6C, the electrode 104 is applied directly to the contact semiconductor layer 102. For this purpose, the buffer 130, preferably made of aluminum gallium nitride, is initially removed, which can be carried out again by a corresponding etching process. In addition, the carrier material 134 is removed from the front side or top side of the semiconductor layer structure. If necessary, the transistor 100 can be applied or bonded to a conductive carrier arranged vertically below the electrode 104 prior to the removal of the carrier material 134.

The embodiment of FIGS. 6A-6F can alternatively also be carried out according to the embodiment of FIGS. 2A-2D, in which the metallization is formed and structured only after removal of the carrier material 134, so that initially a full-surface introduction or irradiation of the laser radiation 133 can be effected, also from vertically upwards to vertically downwards.

1-11. (canceled)

12. A method for producing a vertical semiconductor device including a semiconductor layer structure for forming a semiconductor device based on gallium nitride and at least two electrodes arranged vertically one above the other, wherein the semiconductor layer structure is grown on a substrate, the method comprising the following method steps:
forming a semiconductor layer structure including at least one layer based on gallium nitride on the substrate, the substrate being a foreign substrate; and
introducing laser radiation into the semiconductor layer structure or the substrate, wherein a wavelength of the laser radiation is greater than an optical band gap of gallium nitride, so that the laser radiation causes at least the substrate to separate from at least part of the semiconductor layer structure.

13. The method according to claim 12, wherein the vertical semiconductor device is a transistor.

14. The method according to claim 12, wherein, prior to the introduction of the laser radiation, a carrier material: (i) is arranged on a side of the semiconductor layer structure facing away from the substrate, and/or (ii) is bonded to the semiconductor layer structure.

15. The method according to claim 12, wherein a vertically upper metallization of the semiconductor layer structure is formed prior to the introduction of the laser radiation and the laser radiation is introduced only into gaps in a lateral surface that do not contain any metallization.

16. The method according to claim 14, wherein a bonding to the carrier substrate and the introduction of the laser radiation are effected before a vertically upper metallization of the semiconductor layer structure is formed.

17. The method according to claim 12, wherein the separation takes place along a surface of the substrate.

18. The method according to claim 12, wherein the separation takes place in an intermediate layer that is grown vertically above the substrate, but is formed vertically below a drift layer and/or vertically below a contact semiconductor layer.

19. The method according to claim 12, wherein: (i) the semiconductor layer structure is produced on the substrate and/or layers applied on the substrate, the substrate having been previously already been separated by laser radiation from a semiconductor layer structure applied thereon, and/or (ii) after at least the substrate is separated from at least part of the semiconductor layer structure, the substrate and/or the layers remaining on the substrate after the separation are prepared for reuse of the substrate to form a semiconductor layer structure based on gallium nitride.

20. The method according to claim 12, wherein, after the separation of at least the substrate, a vertically lower electrode is deposited or grown on the semiconductor layer structure.

21. The method according to claim 12, the formation of the semiconductor layer structure on the substrate also includes a formation of a separating layer which is separated by the introduction of the laser radiation, wherein the separation is formed within the separating layer.

22. The method according to claim 21, wherein the seoarating layer is of an indium-gallium-nitrite material.

23. The method according to claim 12, wherein the separation using the laser radiation is supported by a coupling of ultrasound and/or megasound into: (i) the substrate, and/or (ii) the semiconductor layer structure.

24. A semiconductor device based on gallium nitride and at least two electrodes arranged vertically one above the other, wherein the semiconductor layer structure is grown on a substrate, the semiconductor device having been produced by:
formation of a semiconductor layer structure including at least one layer based on gallium nitride on the substrate, the substrate being a foreign substrate; and
introduction of laser radiation into the semiconductor layer structure or the substrate, wherein a wavelength of the laser radiation is greater than an optical band gap of gallium nitride, so that the laser radiation causes at least the substrate to separate from at least part of the semiconductor layer structure.
